(19) United States
(12) Patent Application Publication
(10) Pub. No.: US 2025/0385145 A1
(43) Pub. Date: Dec. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Wei-Chun CHEN, Taichung City (TW); Yuan-Ping YEH, Taichung City (TW); Yu-Cheng PAI, Taichung City (TW)

(73) Assignee: SILICONWARE PRECISION INDUSTRIES CO., LTD., Taichung City (TW)

(21) Appl. No.: 18/774,402

(22) Filed: Jul. 16, 2024

(30) Foreign Application Priority Data
Jun. 13, 2024 (TW) 113121908

(51) Int. Cl. H01L 23/13; H01L 21/48; H01L 21/56; H01L 23/00; H01L 23/31; H01L 23/498; H01L 25/065

(52) U.S. Cl. CPC H01L 23/13; H01L 21/486; H01L 21/56; H01L 23/3135; H01L 23/49827; H01L 25/0657; H01L 24/13; H01L 24/16; H01L 24/32; H01L 24/73; H01L 2224/13147; H01L 2224/16235; H01L 2224/32225; H01L 2224/73253; H01L 2225/06548; H01L 2225/06562; H01L 2225/06572; H01L 2924/15153

(57) ABSTRACT

An electronic package and a manufacturing method thereof are provided, in which a first recessed portion and a second recessed portion are respectively formed on a first side and a second side of a core board, a first electronic element and a second electronic element are respectively disposed in the first recessed portion and the second recessed portion, an insulating layer fills the first recessed portion and the second recessed portion to cover the first electronic element and the second electronic element, a circuit layer is formed on the insulating layer, and a plurality of conductive blind vias are formed in the insulating layer and electrically connected to the circuit layer as well as the first and second electronic elements, so that the first electronic element and the second electronic element will not offset when the insulating layer fills the first recessed portion and the second recessed portion.

### BACKGROUND

### 1. Technical Field

The present disclosure relates to a semiconductor packaging technology, and more particularly, to an electronic package and a manufacturing method thereof.

### 2. Description of Related Art

With the evolution of semiconductor packaging technology, different packaging types have been developed for semiconductor devices, wherein, in a semiconductor device, a chip is disposed on a package substrate, the chip is electrically connected onto the package substrate, and then the chip is covered with an encapsulating colloid. However, in order to meet the thinning requirements, in the industry, the chip is embedded in a package substrate to reduce the size of the overall semiconductor device and improve the electrical performance, thereby becoming a trend of packaging.

FIG. 1A to FIG. 1G are schematic cross-sectional views illustrating a manufacturing method of a conventional semiconductor package 1.

As shown in FIG. 1A, a core board 10 is provided with wiring layers 101 on its upper and lower sides, and at least one conductive via 102 electrically connected to the wiring layers 101 is formed in the core board 10.

As shown in FIG. 1B, an opening 100 is formed on the core board 10 and penetrates through the core board 10.

As shown in FIG. 1C, a semiconductor chip 11 having a plurality of electrode pads 110 is placed in the opening 100.

As shown in FIG. 1D, a dielectric layer 14 is pressed on the upper and lower sides of the core board 10, so that the dielectric layer 14 fills the opening 100 to cover the semiconductor chip 11.

As shown in FIG. 1E, a plurality of blind holes 140 are formed on the dielectric layer 14, so that part of the surface of each of the electrode pads 110 and part of the surface of the wiring layer 101 are exposed from the blind holes 140.

As shown in FIG. 1F, a circuit layer 13 is respectively formed on each side of the dielectric layer 14, and the circuit layer 13 forms a plurality of conductive blind vias 130 in the blind holes 140 to electrically connect the electrode pads 110 and the wiring layers 101.

As shown in FIG. 1G, a solder-resist layer 15 is formed on each side of the dielectric layer 14 and each of the circuit layers 13, and a plurality of openings 150 are formed on the solder-resist layer 15 so that parts of the surface of the circuit layer 13 are exposed from the openings 150.

However, in the manufacturing method of the conventional semiconductor package 1, an opening 100 needs to be formed in the core board 10 to place the semiconductor chip 11. If the depth D of the opening 100 is greater than the thickness H of the semiconductor chip 11, when the dielectric layer 14 fills the opening 100, the dielectric layer 14 will impact the semiconductor chip 11 and cause the semiconductor chip 11 to shift (as shown in FIG. 1D, the left and right distances t1 and t2 between the semiconductor chip 11 and the walls of the opening 100 are different, where t1<t2) or even skew. As a result, in the subsequent process, the electrode pads 110 of the semiconductor chip 11 cannot be accurately aligned with the blind holes 140, resulting in that the conductive blind vias 130 and the electrode pads 110 are not effectively electrically connected, thereby resulting in poor reliability of the product.

Therefore, how to avoid the deficiencies of the prior art has become an urgent issue to be solved.

### SUMMARY

In view of the various deficiencies of the prior art, the present disclosure provides an electronic package, which comprises: a core board having a first side and a second side opposite to the first side, wherein a first recessed portion and a second recessed portion that do not penetrate through the core board are respectively formed on the first side and the second side; a first electronic element disposed in the first recessed portion; a second electronic element disposed in the second recessed portion; an insulating layer formed on the first side and the second side of the core board, wherein the insulating layer fills the first recessed portion and the second recessed portion and covers the first electronic element and the second electronic element; a circuit layer formed on the insulating layer; and a plurality of conductive blind vias formed in the insulating layer and electrically connected to the circuit layer as well as the first electronic element and the second electronic element.

The present disclosure also provides a method of manufacturing an electronic package, which comprises: providing a core board having a first side and a second side opposite to the first side, wherein a first recessed portion and a second recessed portion that do not penetrate through the core plate are respectively formed on the first side and the second side; placing a first electronic element in the first recessed portion, and placing a second electronic element in the second recessed portion; forming an insulating layer on the first side and the second side of the core board, wherein the insulating layer fills the first recessed portion and the second recessed portion and covers the first electronic element and the second electronic element; and forming a circuit layer on the insulating layer, and forming a plurality of conductive blind vias in the insulating layer, wherein the plurality of conductive blind vias are electrically connected to the circuit layer as well as the first electronic element and the second electronic element.

In the aforementioned electronic package and method, a position of the first recessed portion and a position of the second recessed portion are not aligned.

In the aforementioned electronic package and method, a position of the first electronic element and a position of the second electronic element are not aligned.

In the aforementioned electronic package and method, wiring layers are respectively formed on the first side and the second side, and a conductive via electrically connected to the wiring layers is formed in the core board.

In the aforementioned electronic package and method, the insulating layer has a plurality of blind holes, and the conductive blind vias are formed in the blind holes.

To sum up, in the electronic package and its manufacturing method of the present disclosure, misaligned and unpenetrated recessed portions are formed on both sides of the core board for accommodating the first electronic element and the second electronic element, so that the first electronic element and the second electronic element will not offset or skew when the insulating layer fills the first recessed portion and the second recessed portion. Therefore, compared with the prior art, when manufacturing the blind holes of the present disclosure, the first electronic element and the second electronic element can be accurately aligned with the blind holes, so that the conductive blind vias and the first electronic element and the second electronic element can be effectively electrically connected to improve product reliability.

### BRIEF DESCRIPTION OF THE DRAWINGS

FIG. 1A to FIG. 1G are schematic cross-sectional views illustrating a manufacturing method of a conventional semiconductor package. FIG. 2A to FIG. 2G are schematic cross-sectional views illustrating a

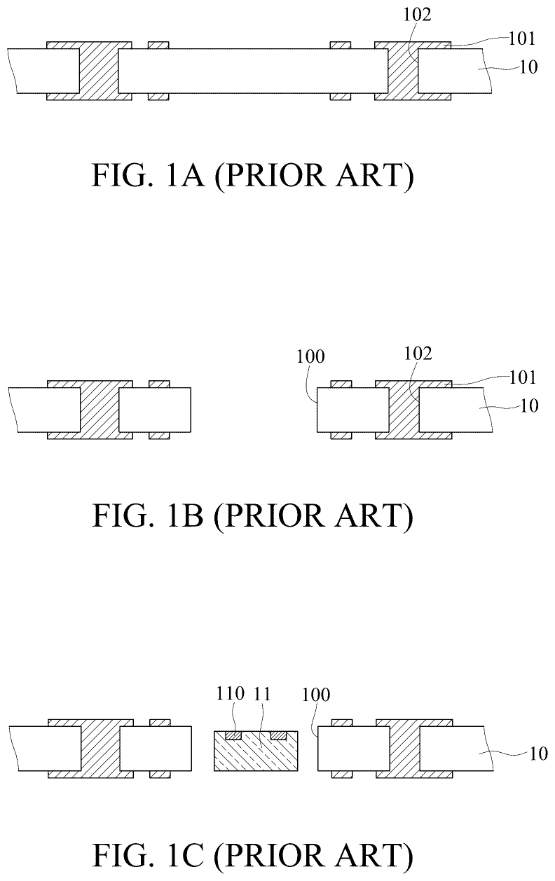

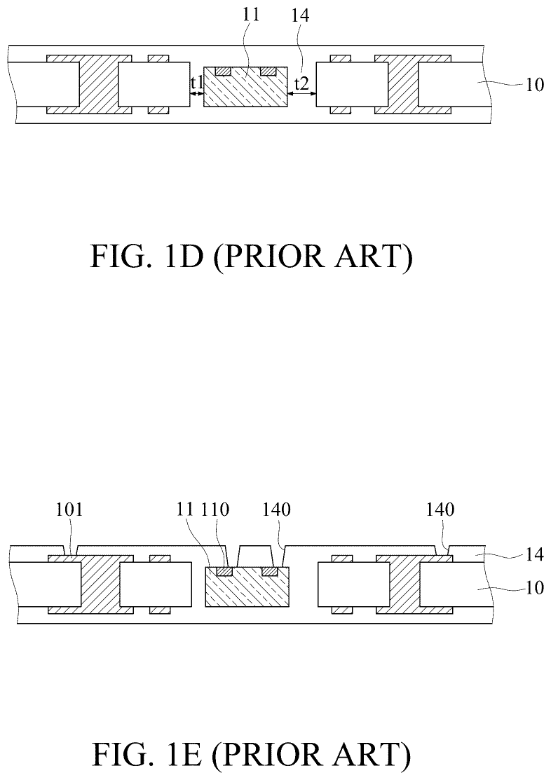

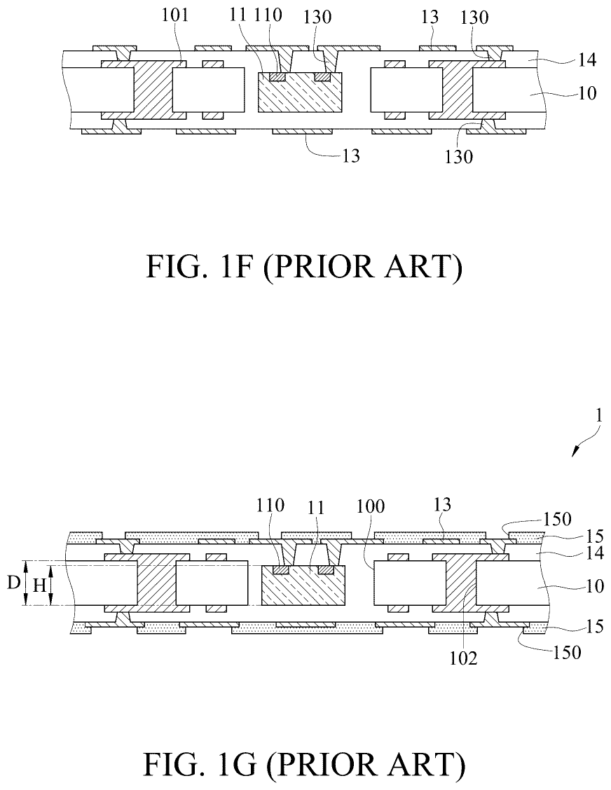

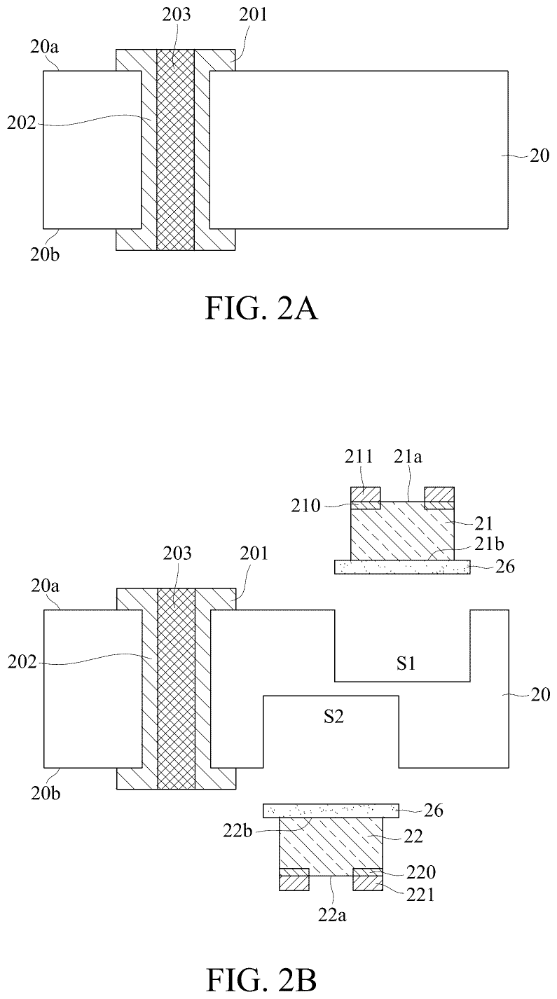

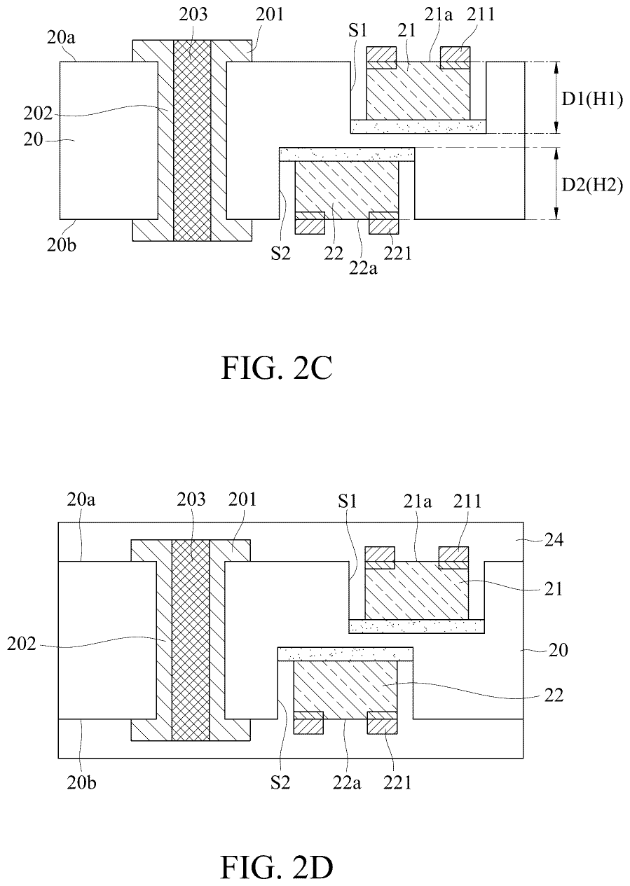

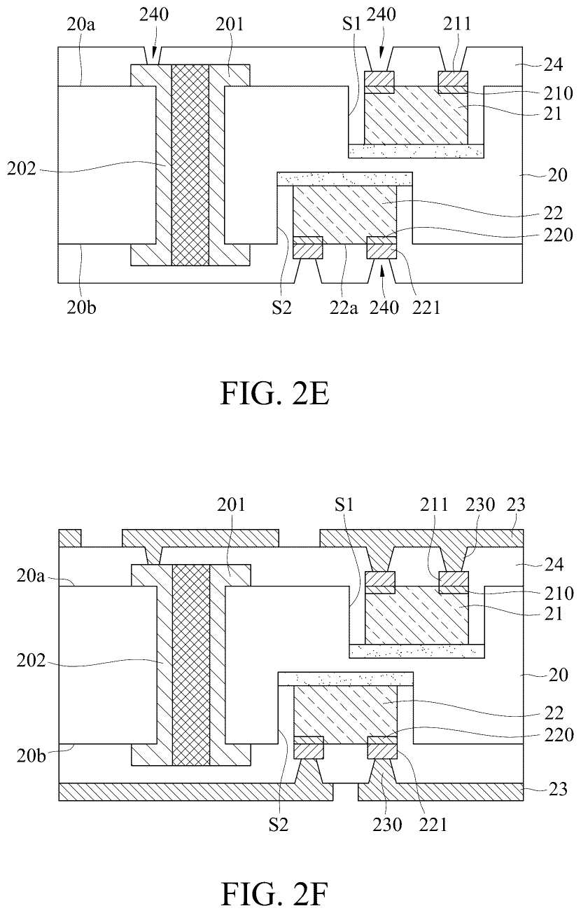

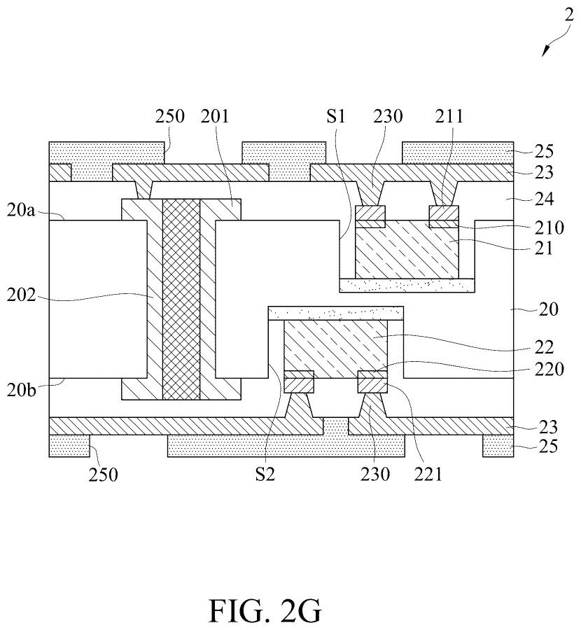

manufacturing method of an electronic package according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

FIG. 2A to FIG. 2G are schematic cross-sectional views illustrating a manufacturing method of an electronic package 2 according to the present disclosure.

As shown in FIG. 2A, a core board 20 is provided and has a first side 20a and a second side 20b opposite to the first side 20a. A wiring layer 201 is formed on the first side 20a and the second side 20b respectively, and at least one conductive via 202 electrically connected to the wiring layers 201 is formed in the core board 20.

In one embodiment, the core board 20 may be a board containing bismaleimide triazine (BT), prepreg (PP), or other materials, and the wiring layer 201 can be formed by electroplating metal (such as copper) or other methods.

Furthermore, the conductive via 202 is a hollow copper pillar, which can be filled with a plugging material 203 in the hollow. For example, the plugging material 203 can be an insulating material or a conductive material, and the present disclosure is not particularly limited to as such. It should be understood that in other embodiments, the conductive via 202 can also be a solid metal pillar without being filled with the plugging material 203.

As shown in FIG. 2B, a first recessed portion S1 is formed on the first side 20a of the core board 20, and a second recessed portion S2 is formed on the second side 20b of the core board 20, so that the position of the first recessed portion S1 and the position of the second recessed portion S2 are not aligned.

In one embodiment, the position of the first recessed portion S1 and the position of the second recessed portion S2 are misaligned from each other.

Furthermore, the first recessed portion S1 and/or the second recessed portion S2 can be formed by drilling, etching, laser, or other methods. It should be understood that the first recessed portion S1 and the second recessed portion S2 can be formed in the same or different ways.

As shown in FIG. 2C, a first electronic element 21 is placed in the first recessed portion S1, and a second electronic element 22 is placed in the second recessed portion S2, so that the position of the first electronic element 21 and the position of the second electronic element 22 are not aligned.

In one embodiment, the first electronic element 21 can be an active element, a passive element, or a combination of the active element and the passive element, wherein the active element is, for example, a semiconductor chip, and the passive element is, for example, a resistor, a capacitor, or an inductor. For example, the first electronic element 21 is a semiconductor chip and has an active surface 21a and an inactive surface 21b opposite to the active surface 21a, and the active surface 21a has a plurality of electrode pads 210, so that the inactive surface 21b of the first electronic element 21 is fixed in the first recessed portion S1 via an adhesive layer 26, with the active surface 21a facing outward. Furthermore, conductive bumps 211 such as copper pillars can be formed on the electrode pads 210 as required.

Furthermore, the second electronic element 22 can be an active element, a passive element, or a combination of the active element and the passive element, wherein the active element is, for example, a semiconductor chip, and the passive element is, for example, a resistor, a capacitor, or an inductor. For example, the second electronic element 22 is a semiconductor chip and has an active surface 22a and an inactive surface 22b opposite to the active surface 22a, and the active surface 22a has a plurality of electrode pads 220, so that the inactive surface 22b of the second electronic element 22 is fixed in the second recessed portion S2 via the adhesive layer 26, with the active surface 22a facing outward. Furthermore, conductive bumps 221 such as copper pillars can be formed on the electrode pads 220 as required.

In addition, the thickness H1 of the first electronic element 21 (together with the adhesive layer 26) is greater than or equal to the depth D1 of the first recessed portion S1, and the thickness H2 of the second electronic element 22 (together with the adhesive layer 26) is greater than or equal to the depth D2 of the second recessed portion S2.

In addition, the position of the first electronic element 21 and the position of the second electronic element 22 are misaligned from each other.

As shown in FIG. 2D, an insulating layer 24 is formed on the first side 20a and the second side 20b of the core board 20, so that the insulating layer 24 fills the first recessed portion S1 and the second recessed portion S2.

In one embodiment, the insulating layer 24 is a dielectric layer and is made of Ajinomoto build-up film (ABF), polybenzoxazole (PBO), polyimide (PI), prepreg (PP), or other dielectric materials.

As shown in FIG. 2E, a plurality of blind holes 240 are formed on each of the insulating layers 24, so that the electrode pads 210, 220 (or the conductive bumps 211, 221) are exposed from the blind holes 240.

In one embodiment, the blind holes 240 can be formed by drilling, etching, laser, exposure and development, or other patterning methods, and the blind holes 240 can expose parts of the surface of the wiring layer 201 as needed.

As shown in FIG. 2F, a circuit layer 23 is formed on each of the insulating layers 24, and a plurality of conductive blind vias 230 electrically connected to the electrode pads 210, 220 (or the conductive bumps 211, 221) and the wiring layer 201 are formed in the blind holes 240.

In one embodiment, the circuit layer 23 and the conductive blind vias 230 can be integrally formed by electroplating metal (such as copper) or other methods.

As shown in FIG. 2G, an insulating protective layer 25 is formed on each of the insulating layers 24 and each of the circuit layers 23, and a plurality of openings 250 are formed on the insulating protective layer 25, so that parts of the surface of the circuit layer 23 are exposed from the openings 250.

In one embodiment, the insulating protective layer 25 is made of solder-resist material such as solder mask (e.g., green solder mask), graphite (e.g., ink), or other materials.

Therefore, in the present disclosure, misaligned and unpenetrated recessed portions are formed on both sides of the core board 20 to accommodate the first electronic element 21 and the second electronic element 22, so that the first electronic element 21 (and/or the second electronic element 22) will not be offset or skewed when the insulating layer 24 is filled into the first recessed portion S1 (and/or the second recessed portion S2). Therefore, compared with the prior art, when manufacturing the blind holes 240 of the present disclosure, each of the electrode pads 210, 220 and each of the blind holes 240 can be accurately aligned, so that each of the conductive blind vias 230 and each of the electrode pads 210, 220 can be effectively electrically connected to improve product reliability. In addition, the first recessed portion S1 and the second recessed portion S2 do not penetrate through the core board 20, so that a plurality of electronic elements can be embedded on both sides of the core board 20, thereby improving the electrical function of the overall electronic package.

Furthermore, through the design that the position of the first recessed portion S1 and the position of the second recessed portion S2 are not aligned (or the position of the first electronic element 21 and the position of the second electronic element 22 are not aligned), the impact force on the first electronic element 21 and the second electronic element 22 is mitigated when the insulating layer 24 fills the first recessed portion S1 and the second recessed portion S2. Therefore, the positioning of the first electronic element 21 and the second electronic element 22 can be ensured to prevent problems such as offset or skew from occurring to the first electronic element 21 and the second electronic element 22.

The present disclosure also provides an electronic package 2, which comprises: a core board 20, at least one first recessed portion S1, at least one second recessed portion S2, at least one first electronic element 21, at least one second electronic element 22, an insulating layer 24, a circuit layer 23 and a plurality of conductive blind vias 230.

The core board 20 has a first side 20a and a second side 20b opposite to the first side 20a, and has a first recessed portion S1 and a second recessed portion S2 on the first side 20a and the second side 20b respectively.

The first electronic element 21 is disposed in the first recessed portion S1.

The second electronic element 22 is disposed in the second recessed portion S2.

The insulating layer 24 is formed on the first side 20a and the second side 20b of the core board 20 and is filled in the first recessed portion S1 and the second recessed portion S2 to cover the first electronic element 21 and the second electronic element 22. The circuit layer 23 is formed on the insulating layer 24.

The conductive blind vias 230 are formed in the insulating layer 24 and electrically connected to the circuit layer 23 as well as the first electronic element 21 and the second electronic element 22.

In one embodiment, the position of the first recessed portion S1 and the position of the second recessed portion S2 are not aligned.

In one embodiment, the position of the first electronic element 21 and the position of the second electronic element 22 are not aligned.

In one embodiment, the insulating layer 24 has a plurality of blind holes 240, wherein the conductive blind vias 230 are formed in the blind holes 240.

To sum up, in the electronic package and its manufacturing method of the present disclosure, misaligned and unpenetrated recessed portions are formed on both sides of the core board for accommodating electronic elements, so that the electronic elements will not offset or skew when the insulating layer fills the recessed portions. Therefore, the electronic elements and the conductive blind vias of the present disclosure can be effectively electrically connected to improve the reliability of the product.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a core board having a first side and a second side opposite to the first side, wherein a first recessed portion and a second recessed portion that do not penetrate through the core board are respectively formed on the first side and the second side;
a first electronic element disposed in the first recessed portion;
a second electronic element disposed in the second recessed portion;
an insulating layer formed on the first side and the second side of the core board, wherein the insulating layer fills the first recessed portion and the second recessed portion and covers the first electronic element and the second electronic element;
a circuit layer formed on the insulating layer; and
a plurality of conductive blind vias formed in the insulating layer and electrically connected to the circuit layer as well as the first electronic element and the second electronic element.

2. The electronic package of claim 1, wherein a position of the first recessed portion and a position of the second recessed portion are not aligned.

3. The electronic package of claim 1, wherein a position of the first electronic element and a position of the second electronic element are not aligned.

4. The electronic package of claim 1, wherein wiring layers are respectively formed on the first side and the second side.

5. The electronic package of claim 4, wherein a conductive via electrically connected to the wiring layers is formed in the core board.

6. The electronic package of claim 1, wherein the insulating layer has a plurality of blind holes, and the conductive blind vias are formed in the blind holes.

7. A method of manufacturing an electronic package, comprising:
providing a core board having a first side and a second side opposite to the first side, wherein a first recessed portion and a second recessed portion that do not penetrate through the core plate are respectively formed on the first side and the second side;
placing a first electronic element in the first recessed portion, and placing a second electronic element in the second recessed portion;
forming an insulating layer on the first side and the second side of the core board, wherein the insulating layer fills the first recessed portion and the second recessed portion and covers the first electronic element and the second electronic element; and
forming a circuit layer on the insulating layer, and forming a plurality of conductive blind vias in the insulating layer, wherein the plurality of conductive blind vias are electrically connected to the circuit layer as well as the first electronic element and the second electronic element.

8. The method of claim 7, wherein a position of the first recessed portion and a position of the second recessed portion are not aligned.

9. The method of claim 7, wherein a position of the first electronic element and a position of the second electronic element are not aligned.

10. The method of claim 7, wherein wiring layers are respectively formed on the first side and the second side.

11. The method of claim 10, wherein a conductive via electrically connected to the wiring layers is formed in the core board.

12. The method of claim 7, wherein the insulating layer has a plurality of blind holes, and the conductive blind vias are formed in the blind holes.
